(19) United States
(12) Patent Application Publication
(10) Pub. No.: US 2011/0121827 A1
(43) Pub. Date: May 26, 2011

(54) SLOTTED CURRENT TRANSDUCER USING MAGNETIC FIELD POINT SENSORS

(76) Inventors: Christopher Paul Yakymyshyn, Seminole, FL (US); Pamela Jane Hamilton, Seminole, FL (US)

(21) Appl. No.: 12/672,271

(22) PCT Filed: Aug. 6, 2008
(86) PCT No.: PCT/US08/72390

§ 371 Date: Feb. 4, 2010

Related U.S. Application Data
(60) Provisional application No. 60/954,296, filed on Aug. 6, 2007.

(51) Int. Cl. G01R 33/06; G01R 33/02

(52) U.S. Cl. 324/251; 324/244

(57) ABSTRACT

A current transducer is disclosed that is capable of measuring DC or AC currents in a conductor. The transducer housing has one or more slots into which a conductor is located. The current transducer maintains accuracy independent of the conductor position.

### CROSS REFERENCE TO PRIOR APPLICATION

This application claims the priority of U.S. Provisional Application Ser. No. 60/954,296 filed Aug. 6, 2007 and entitled “Slotted Current Transducer using magnetic field point sensors”, the subject matter of which is incorporated herein by reference.

### FIELD OF THE INVENTION

The present invention relates to a current sensor for measuring alternating and direct electrical current such as the current of a high-voltage power transmission line or a substation bus conductor.

### DESCRIPTION OF THE PRIOR ART

A variety of current measurement techniques are known in the art, including current transformers, Rogowski coil transformers, resistive shunts, magnetic field point sensors, magnetic field line integral sensors, and line integral optical current sensors. Prior U.S. Pat. No. 7,164,263 issued Jan. 17, 2007 discloses the use of a plurality of magnetic field sensors positioned along a closed path that encircles a current carrying conductor to create an output signal that represents the current in the conductor. Edwards describes in U.S. Pat. No. 5,057,769 (Oct. 15, 1991) a C-shaped current sensor with an open slot into which the conductor may be positioned, based on using an open Rogowski coil wherein a pair of compensating coils are positioned near the opening to compensate for the lack of windings in the opening.

There exists a need for a current sensor that can meet the accuracy requirements for revenue metering in power utility applications, is lightweight, low cost, has a bandwidth from DC to >10 kiloHertz, and can be clamped in place without having to disconnect the conductor being monitored.

### SUMMARY OF PRESENT INVENTION

Briefly, a prior art (Yakymyshyn, et al. U.S. Pat. No. 7,164,263 issued Jan. 17, 2007) current sensor for applications including but not limited to DC, 50 Hz and 60 Hz power lines (or substation bus conductors) consists of a plurality of magnetic field sensors oriented and located around a current carrying conductor. The magnetic field sensors are preferably Hall effect sensors, although a variety of other magnetic field sensors can be substituted. The sensors are attached to a printed circuit board that is placed in a protective housing. The magnetic field sensors are selected to be sensitive to one vector component of the magnetic field, and the sensitivity axis of each sensor is oriented to be tangential to a circle circumscribing, and approximately centered on, the current carrying conductor. As such, the sensors monitor the azimuthal component of the magnetic field, which is directly related to the conductor current. The number of sensors is selected to provide an accurate approximation to Ampere's law. The magnetic field sensor outputs are combined in a summing amplifier. The output of the summing amplifier is passed through a filter circuit to compensate for time delays in the magnetic field sensors and the amplifier. The filter output passes through a second amplifier to provide a desired amplitude gain, resulting in an output voltage or current that is substantially proportional to the current in the current carrying conductor.

In the present invention, the closed path that encircles the current carrying conductor and the number of magnetic field sensors are selected so that the distance between adjacent magnetic field sensors is larger than the diameter of the current carrying conductor. In this way, the current transducer can be slipped onto the conductor without breaking the conductor or opening the current transducer. Provided the conductor is located in the slot at a location that falls within the area encircled by the closed path of magnetic field sensors, the output signal from the current transducer will maintain a highly accurate measurement of the current in the current carrying conductor.

One advantage of the present invention is that it is very low in weight.

Another advantage of the present invention is that the current sensor can be slipped over a current carrying conductor without breaking or disconnecting the conductor.

Another advantage of the present invention is that revenue accuracy measurements can be made for power system applications.

Another advantage of the present invention is that relaying accuracy can be achieved for power system applications.

Another advantage of the present invention is that high measurement accuracy is independent of the location of the current carrying conductor within the housing slot, provided the conductor is located within the closed path along which the magnetic field point sensors are located.

Another advantage of the present invention is that high measurement accuracy is independent of conductor tilt relative to the sensor housing.

Another advantage of the present invention is that high measurement accuracy is independent of the rotation angle of the current sensor.

Another advantage of the present invention is that high measurement accuracy is independent of stray magnetic fields generated by current carrying conductors located nearby.

Another advantage of the present invention is that high accuracy is maintained because no magnetic core is included in the sensor design.

Another advantage of the present invention is that the sensor can provide high measurement accuracy for alternating currents and direct currents.

Another advantage of the present invention is that multiple slots can be included in the same current sensor to measure multiple current carrying conductors.

### BRIEF DESCRIPTION OF DRAWINGS

FIG. 1 is a drawing of the current sensor.

FIG. 2 is a block diagram of the prior art current sensor electronic circuit.

FIG. 3 is a graph of the current sensor error versus the number of sensor elements required.

FIG. 4 is a schematic diagram of the current sensor.

FIG. 5 is a drawing of the housing.

### DETAILED DESCRIPTION OF THE PREFERRED EMBODIMENTS

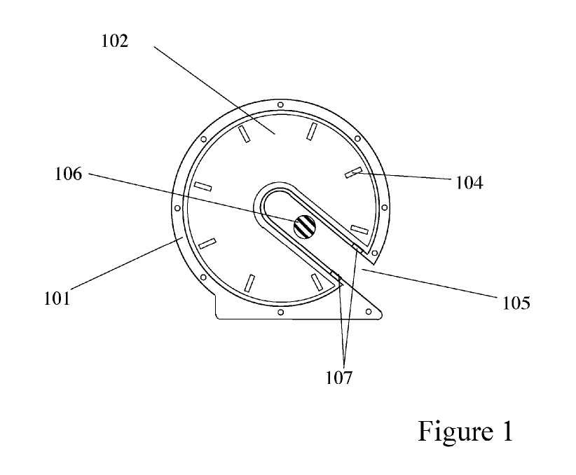

A current sensor for applications including but not limited to DC, 50 Hz and 60 Hz power lines is described that consists of a plurality of magnetic field sensors oriented and located around a current carrying conductor. The magnetic field sensors are preferably Hall effect sensors, although a variety of other magnetic field sensors can be substituted, including but not limited to magnetoresistive, giant magnetoresistive, or magnetostrictive sensors. The current sensor is shown in FIG. 1. A printed circuit board 102 is placed in a protective, hermetically sealed housing 101 and the sensors are arranged to form a closed path around a current carrying conductor 106. The housing has one or more slots 105, allowing the housing 101 to slide onto a continuous conductor without breaking the conductor at either end. A plurality of magnetic field sensors 104 is placed on the printed circuit board. The magnetic field sensors 104 are selected to be sensitive to one vector component of the magnetic field, and the sensitivity axis of each sensor is oriented to be tangential to a circle circumscribing, and approximately centered on, the current carrying conductor. The sensors are equally spaced along the circumference of the above-mentioned circle. As such, the sensors monitor the azimuthal component of the magnetic field, which is directly related to the conductor current through Ampere's law. Slots 107 are formed into the end faces of the housing 101 to minimize the effects of eddy currents induced in housing 101 by current carrying conductor 106 on the magnitude and phase angle error of the output of the current sensor. The slots 107 are filled with an electrically insulating material to form a hermetic seal while preventing eddy currents from flowing in this region.

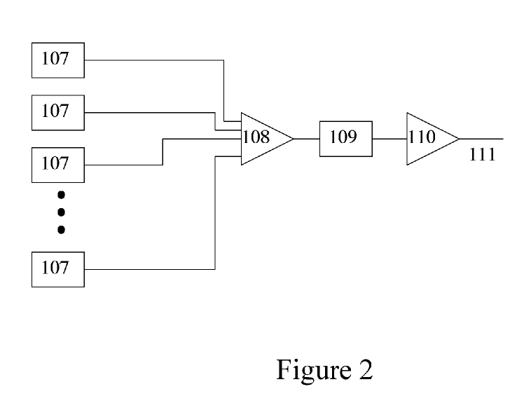

FIG. 2 is a schematic diagram of the current sensor circuitry. The magnetic field sensor outputs 107 are combined in a summing amplifier 108. The output of the summing amplifier is passed through a filter circuit 109 to compensate for time delays in the magnetic field sensors and the amplifier. The filter is preferentially a low-pass filter with a cutoff frequency set by the upper frequency range desired, in series with a high pass filter having a cut-off frequency well above the frequency range of interest for measurements. The low pass filter removes undesired high frequency noise, whereas the high pass filter provides a phase lead compensation for periodic signals to compensate for a phase lag due to a time delay in the magnetic field sensors. The filter output passes through a second amplifier 110 to provide a desired amplitude gain, resulting in an output voltage or current at 111 that is substantially proportional to the current in the current carrying conductor.

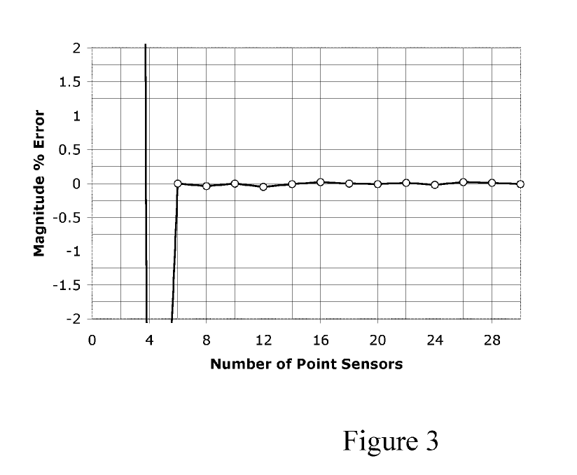

The total number of sensors and the spacing between the sensors along the sensing path is determined by the accuracy required and the proximity of other magnetic fields or materials with high magnetic permeability. Computer modeling is used to calculate the expected error in the magnitude ratio and phase angle of the output signal, when the sensor is located near a second current carrying conductor, near a metallic object having a large magnetic permeability, or when the encircled current carrying conductor is not centered in the sensor housings, or is not collinear with the central axis of the housings. Limits in the variations in the sensitivity of each magnetic field sensor are modeled to determine the variation in sensitivity due to stray magnetic fields and due to rotation of the sensor housings around the current carrying conductor. An example of a calculation is shown in FIG. 3, where the error in amplitude measurement is plotted as a function of the number of equally spaced sensor elements 104. The errors are introduced by the presence of a second conductor placed 60 mm away from the current carrying conductor, and carrying a current of 25% in magnitude of the main current. For this particular disturbance case, the number of sensors required to achieve <0.3% errors is at least 6 elements. It is to be appreciated by someone skilled in the art that other perturbation conditions exist, including but not limited to conductor off-centering, conductor tilt, secondary conductor locations and current levels, variations in responsivity of the sensor elements, conductor diameter, and sensor element position along the sensing circle.

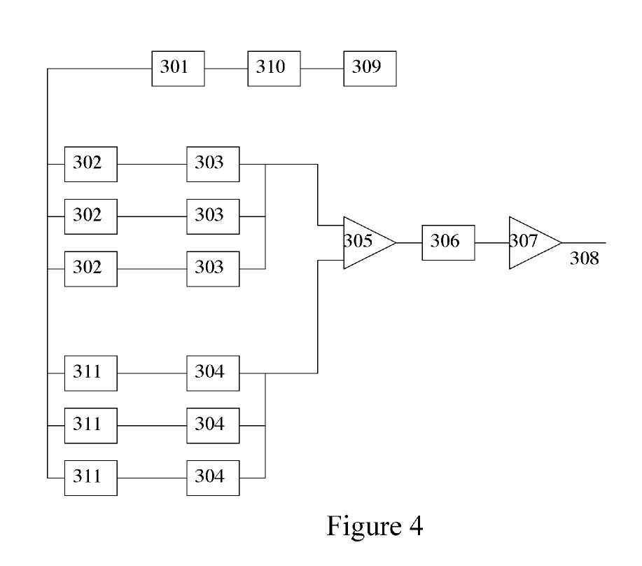

The schematic diagram shown in FIG. 4 uses a total of six magnetic field sensors for illustration purposes. However, someone skilled in the art will recognize that the number of sensors is adjustable to other values, with the precise number depending on the size of the individual magnetic field sensors relative to the size of the overall current sensor housing, the power supply requirements, and the desired immunity to external magnetic fields. It is important to realize that four or fewer magnetic field sensors will not be sufficient for the current sensor to achieve a magnitude accuracy equal to, or less than 0.3% and a phase angle accuracy equal to, or less than 0.1 degrees of phase.

The magnetic field sensors are electronic integrated circuits with an output signal that is composed of a DC offset voltage that does not depend on magnetic field intensity, superimposed with a second voltage that varies with the magnitude and polarity of the magnetic field created by the electrical current in the conductor (e.g. a 60 Hz sinusoidal signal). To achieve the highest sensitivity, the DC offset voltage must be removed from the output signal. The disclosed method is shown in FIG. 4. This is achieved by orienting half of the magnetic field sensors 302 with a positive polarity (that is, the output voltage increases when a magnetic field is generated in the clockwise direction around the current carrying conductor), and half of the magnetic field sensors 311 with the negative polarity (that is, the output voltage increases when a magnetic field is generated in the counter-clockwise direction around the current carrying conductor). The signals from the positive polarity sensors are summed together using impedance elements 303, and the signals from the negative polarity sensors are summed together separately using impedance elements 304. Each summed signal has a DC offset voltage that is the average of the DC offset voltages of the individual magnetic field sensors, and a signal voltage that is proportional to the average magnetic field detected by the magnetic field sensors. Since the same magnetic field sensors are used throughout, the DC offset voltages of the two averaged signals will be effectively equal. The two averaged signals are then differenced in amplifier 305 to create an output signal that has no DC offset voltage, but contains a voltage that is proportional to the average magnetic field seen by all of the magnetic field sensors and thus gives a measure of the current flowing through the conductor. The signal is then passed through a filter 306 and amplifier 307 to generate an output signal 308 that is substantially in phase with the measured current and proportional in magnitude to the measured current. In this way, very small conductor currents can be amplified to generate an output signal that is easily detected. Furthermore, the output signal has a bandwidth that extends down to DC currents.

The magnetic field sensors 302 can be active devices, such as Hall effect sensors, or they can be passive devices, such as air-core inductive coils. In the latter case, the elements 301, 310 and 309 shown in FIG. 4 are not required. In the former case, the magnetic field sensors 302 require a voltage source 301 for operation. The sensors 302 are selected to have a response to the local magnetic field that is linearly proportional to the magnitude of the voltage source 301. This can be used advantageously to compensate for variations in the sensors due, for example, to temperature, by measuring the temperature in the housing with a temperature sensor 309 and performing signal processing on the temperature signal with a signal processor 310. The output of the signal processor 310 controls the value of the voltage source 301 to compensate for the temperature variations in the magnetic field sensors 302. For sensors 302 whose sensitivity to magnetic fields is independent of the voltage source 301, the elements 310 and 309 are not required.

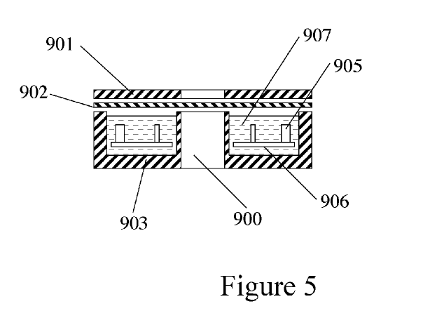

As shown in the cross-section in FIG. 5, the current sensor housing consists of a plate with a trough 903. The printed circuit board 906 carrying the magnetic field sensors 905 and other associated circuitry is mounted into the trough and preferably potted in a flexible compound 907 selected from the list including but not limited to silicone, epoxy, acrylonitrile butadiene styrene (ABS) and polyurethane. A top lid 901 is fastened to the lower assembly with bolts or other suitable fastening means, interposed between which is a sealing and insulating gasket 902 fabricated from a material selected from the list including but not limited to EPDM rubber, silicone and Viton rubber. The potting and gasket form a hermetic seal to protect the printed circuit board 906 from the outside environment.

The housing is preferably fabricated from a metal, but it can be fabricated from an insulating material provided that metallic shielding is placed around the printed circuit boards 906 to provide Faraday shielding of the electronic circuitry from external electric fields. The use of a poor electrically conductive material such as bismuth, stainless steel, carbon-filled polymer or metal/carbon filled epoxy prevents substantial eddy currents from being generated, which can cause measurement errors in both ratio magnitude and phase angle. However, for these materials the Faraday shielding of the printed wiring board is reduced compared with that provided by highly conductive metals such as copper or aluminum.

The use of Aluminum as a housing material provides the added benefit that eddy currents induced in the housing by the magnetic field generated by the current carrying conductor can be exploited to homogenize the magnetic field distribution near the magnetic field sensors. As shown in FIG. 5, an aluminum top plate is secured to the bottom plate with a means that minimizes the creation of closed current paths that encircle the printed circuit board. This can be achieved by using electrically insulating fasteners and an electrically insulating gasket material 902 between the top and bottom plates. When measuring currents, the magnetic field generated by the current carrying conductor is homogenized by eddy currents induced in the sides, top and bottom of the trough containing the printed circuit board, resulting in improved immunity to errors induced by external magnetic fields, external materials with high magnetic permeability, and rotation or translation of the current sensing device.

Moreover, eddy currents can be deleterious to device operation when they encircle the path along which the magnetic field sensors are located. To minimize this effect, the inside surfaces of the slot 900 formed in the plate with trough 903 shown in FIG. 5 are slitted or machined to reduce the effects of eddy currents on the ratio accuracy and phase angle of the current measuring device. The inside surfaces of the plate with trough 903 have slots 107 formed therein to prevent eddy current paths from encircling the path along which the sensors are located. The slots 107 are then filled with an electrically insulating potting compound to form a hermetically sealed surface.

An example of a current sensor is given below. A total of twelve Hall effect magnetic field sensors with matched sensitivities to magnetic fields are placed on the printed circuit board. Six sensors have positive orientation, and six sensors have negative orientation. The outputs of the sensors are averaged and differenced to generate an output voltage. The output voltage is phase shifted with a passive filter circuit. The resulting current sensor has a slot width of 0.75 inches, and a sensitivity of 2 volts per kiloamp. The ratio is linear to within 0.1% of reading from 10 Amps to 1500 Amps (AC rms), and has a noise floor of 0.5 Amp rms with a bandwidth of DC-5 kHz. The output phase angle is stable to within +/−5 minutes over all test conditions. The ratio error is +/−0.3% over a temperature range of −40 to +85 degrees Celcius. Repeated positioning of the current carrying conductor within the slot results in ratio errors of <0.2%. Rotating the current sensor around the current carrying conductor results in errors of <0.2%. Tilting the current sensor relative to the current carrying conductor by +/−30 degrees results in ratio errors of <0.3%. When the current sensor is placed next to (in contact with) a conductor carrying 1000 Amps, the resulting signal level is <1 Amp of induced signal, resulting in a rejection ratio of >60 dB for currents that do not pass through the current sensor slot.

While only certain features of the invention have been illustrated and described herein, many modifications and changes will occur to those skilled in the art. It is, therefore, to be understood that the appended claims are intended to cover all such modifications and changes as fall within the true spirit of the invention.

What is claimed is:

1. A device for measuring electric current in a conductor, comprised of a plurality of magnetic field sensors positioned around a current carrying conductor, where each sensor is sensitive to one vector component of the magnetic field generated by the electric current, where the sensors are positioned along one or more continuous closed paths encircling the conductor, where the sensors have substantially identical sensitivity along each closed path, where the sensors are equally spaced along the length of each closed path, where the vector direction of sensitivity for each sensor is oriented to be tangential with the closed path at each sensor location, where the sensors are enclosed by a housing having at least one slot extending into the area encircled by the said closed path of sensors, where the width of the slot is smaller than the spacing between two adjacent sensors, and where the said current carrying conductor passes through said slot and is positioned within the area enclosed by the said closed path of sensors.

2. The device in claim 1 where the magnetic field sensors are selected from the list including but not limited to Hall effect, magnetoresistive, giant magnetoresistive, magnetostrictive and air-core inductive coil.

3. The device in claim 1 where the continuous closed path is a circle or an ellipse.

4. The device in claim 1 where the number of sensors is selected to range from 3-1000 elements, and more preferably from the range of 6-35 elements.

5. The device in claim 1 where diameter of the closed path encircling the current-carrying conductor along which the sensors are positioned, and the sensor's sensitivity to magnetic field are chosen to provide the desired device response to electric current in the conductor.

6. The device in claim 1 where the sensors are located in a housing that is electrically conductive to provide Faraday shielding from external electric fields.

7. The device in claim 1 where the sensors are located in an electrically insulating housing that has an electrically conductive coating on the inside and/or outside surfaces to provide Faraday shielding for the magnetic field sensors.

8. The device in claim 1 where the sensors and printed circuit boards are potted in a compound to provide protection from the external environment, and is selected from the list that includes but is not limited to silicone, epoxy, acrylonitrile butadiene styrene and polyurethane.

9. A method for measuring electric current in a conductor, comprised of positioning a plurality of magnetic field sensors positioned around a current carrying conductor, where each sensor is sensitive to one vector component of the magnetic field generated by the electric current, where the sensors are positioned along one or more continuous closed paths encircling the conductor, where the sensors have substantially identical sensitivity along each closed path, where the sensors are equally spaced along the length of each closed path, where the vector direction of sensitivity for each sensor is oriented to be tangential with the closed path at each sensor location, where the sensors are enclosed by a housing having at least one slot extending into the area encircled by the said closed path of sensors, where the width of the slot is smaller than the spacing between two adjacent sensors, and where the said current carrying conductor passes through said slot and is positioned within the area enclosed by the said closed path of sensors.
